(19) United States
(12) Patent Application Publication
(10) Pub. No.: US 2026/0185650 A1
(43) Pub. Date: Jul. 2, 2026

(54) BENDABLE DISPLAY DEVICE

(71) Applicant: LG Display Co., Ltd., Seoul (KR)

(72) Inventors: SeungHee Lee, Seoul (KR); Hyosung Lee, Gwangmyeong-si (KR)

(73) Assignee: LG Display Co., Ltd., Seoul (KR)

(21) Appl. No.: 19/435,243

(22) Filed: Dec. 29, 2025

(30) Foreign Application Priority Data
Dec. 30, 2024 (KR) 10-2024-0200090

(51) Int. Cl. F16M 11/10; G02F 1/1333; H05K 7/18

(52) U.S. Cl. CPC F16M 11/10; G02F 1/133305; G02F 1/133314; H05K 7/183; F16M 2200/065; F16M 2200/08

(57) ABSTRACT

A bendable display device may include a support, a driving module rotatably coupled to the support, and having an actuator and a plurality of power transmission units connected to the actuator, and a display panel module coupled to the driving module and bendable, wherein one of the plurality of power transmission units is configured to receive power from the actuator to rotate the display panel module, and another of the plurality of power transmission units is configured to receive power from the actuator to bend at least a portion of the display panel module.

### CROSS-REFERENCE TO RELATED APPLICATIONS

This application claims the priority of Korean Patent Application No. 10-2024-0200090 filed on Dec. 30, 2024, in the Korean Intellectual Property Office, the disclosure of which is incorporated herein by reference.

### FIELD

The present disclosure relates to a bendable display device and, in more detail, a display device capable of bending and rotating as a bendable display device.

### BACKGROUND

Display devices used for a monitor of a computer, a TV, or a mobile phone include an organic light emitting display (OLED) that emits light by itself, and a liquid crystal display (LCD) that requires a separate light source.

Applications of display devices are becoming more diverse, including computer monitors, TVs, and portable devices, as well as vehicles, and research is being conducted on display devices that have a large display area and a reduced volume.

In addition, recently, a bendable display device is attracting attention as a next generation display device. A bendable display device is manufactured by forming a display unit or wiring on a flexible substrate such as plastic, which is a flexible material, to provide a user with a sense of curvature by bending and rotating.

### SUMMARY

An object of the present disclosure is to provide a bendable display device capable of providing a user with a maximized or enhanced sense of curvature of a display panel module.

Another object of the present disclosure is to provide a bendable display device capable of easily bending and rotating a display panel module at an angle desired by a user.

Objects of the present disclosure are not limited to the above-mentioned objects, and other objects not mentioned above can be clearly understood by those skilled in the art from the following descriptions.

To achieve these objects and other advantages and in accordance with the purpose of the present disclosure, as embodied and broadly described herein, a display device according to an example embodiment of the present disclosure may include a support, a driving module rotatably coupled to the support, and having an actuator and a plurality of power transmission units connected to the actuator, and a display panel module coupled to the driving module and bendable, wherein one of the plurality of power transmission units is configured to receive power from the actuator to rotate the display panel module, and another of the plurality of power transmission units is configured to receive power from the actuator to bend at least a portion of the display panel module.

In another aspect of the present disclosure, a display device includes: a display panel configured to display an image, the display panel having a first area and a second area bendable with respect to the first area; a stand supporting the display panel; an actuator at a rear surface of the display panel; a first power transmission unit connected between the actuator and the stand, and configured to be driven by the actuator to tilt the display panel; and a second power transmission unit connected between the actuator and the display panel, and configured to be driven by the actuator to bend the second area of the display panel with respect to the first area.

Other detailed matters of various example embodiments are included in the detailed description and the drawings.

In the bendable display device according to example configurations of the present disclosure, the display panel module may be bent and rotated through the driving module.

The bendable display device according to example embodiments of the present disclosure may provide a maximized or enhanced sense of curvature to a user and may enable the user to view contents from various angles desired by the user.

The bendable display device according to example embodiments of the present disclosure is capable of switching between a basic mode and a bending mode and, when not in use, is capable of increasing space efficiency by switching to a basic mode.

The effects according to the present disclosure are not limited to the contents discussed above, and various additional effects can be attained from the present disclosure.

### BRIEF DESCRIPTION OF DRAWINGS

The accompanying drawings, which are included to provide a further understanding of the present disclosure and are incorporated in and constitute a part of this application, illustrate example embodiments of the present disclosure and together with the description serve to explain various principles of the present disclosure. The above and other aspects, features, and other advantages of the present disclosure can be more clearly understood from the following detailed description taken in conjunction with the accompanying drawings.

FIG. 1 is a front perspective view of a bendable display device according to an example embodiment of the present disclosure.

FIG. 2 is a rear perspective view of the bendable display device according to an example embodiment of the present disclosure.

FIG. 3 is a front perspective view of a bendable display device according to an example embodiment of the present disclosure which is bent and rotated.

FIG. 4 is a rear perspective view of a bendable display device according to an example embodiment of the present disclosure which is bent and rotated.

FIG. 5 is an exploded perspective view of a support and a driving module according to an example embodiment of the present disclosure.

FIG. 6 is an exploded perspective view of a display panel module according to an example embodiment of the present disclosure.

FIG. 7 is a rear view of the bendable display device in which the display panel module according to an example embodiment of the present disclosure is located at a first position.

FIG. 8 is a cross-sectional view taken along the line A-A′ in FIG. 7.

FIG. 9 is a cross-sectional view taken along line B-B′ in FIG. 7.

FIG. 10 is a rear view of the bendable display device in which the display panel module according to an example embodiment of the present disclosure is located at a second position.

FIG. 11 is a cross-sectional view taken along line C-C′ in FIG. 10.

FIG. 12 is a cross-sectional view taken along line D-D′ in FIG. 10.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein and can be implemented in various other forms. The example embodiments are provided by way of example only so that those skilled in the art can more fully understand the features and aspects of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Further, in the following description of the present disclosure, a detailed explanation of known related technologies may be omitted to avoid unnecessarily obscuring the subject matter of the present disclosure. Such terms as “including,” “having,” and “consist of,” where used herein, are generally intended to allow other components to be added unless the terms are used with a more specific term like “only.” Any references to singular may include plural, and vice versa, unless expressly stated otherwise.

Components are to be interpreted to include an ordinary error range even if not expressly stated.

Where the positional relation between two parts is described using such terms as “on,” “above,” “below,” and “next,” one or more parts may be positioned between the two parts unless the terms are used with a more specific term like “immediately” or “directly.”

Where an element or layer is described as being disposed “on” one other element or layer, the element or layer may be disposed directly on the one other element or layer, or a third layer or element may be interposed therebetween.

Although terms like “first” and “second” may be used for describing various components, these components are not limited by these terms. These terms are merely used for referring to one component separately from the other components. Therefore, a first component mentioned below may be a second component, and vice versa, in a technical concept of the present disclosure.

Like reference numerals generally denote like elements throughout the disclosure unless otherwise specified.

A size and a thickness of each component illustrated in the drawing are illustrated for convenience of description, and the present disclosure is not limited to the size and the thickness of the component illustrated.

The features of various example embodiments of the present disclosure can be partially or entirely adhered to or combined with each other and can be interlocked and operated in technically various ways, and the example embodiments can be carried out independently of or in association with each other.

Hereinafter, example embodiments of the present disclosure will be described in detail with reference to accompanying drawings.

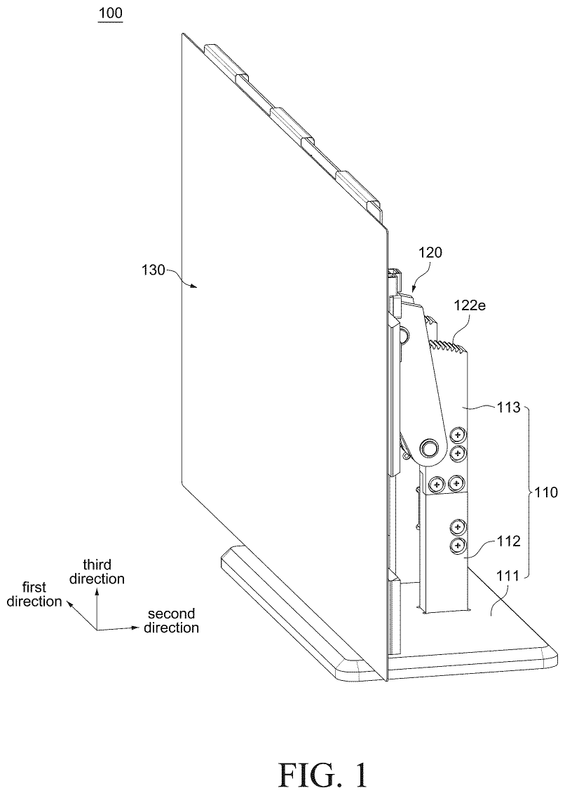

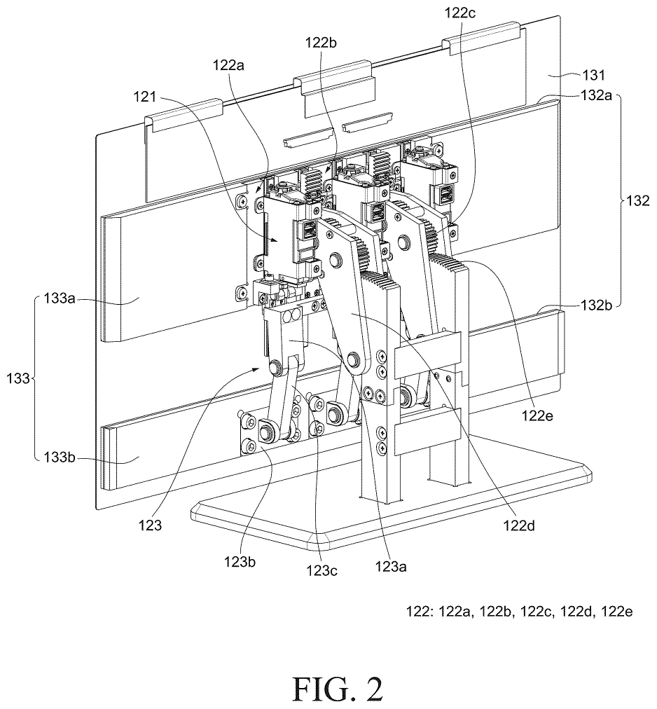

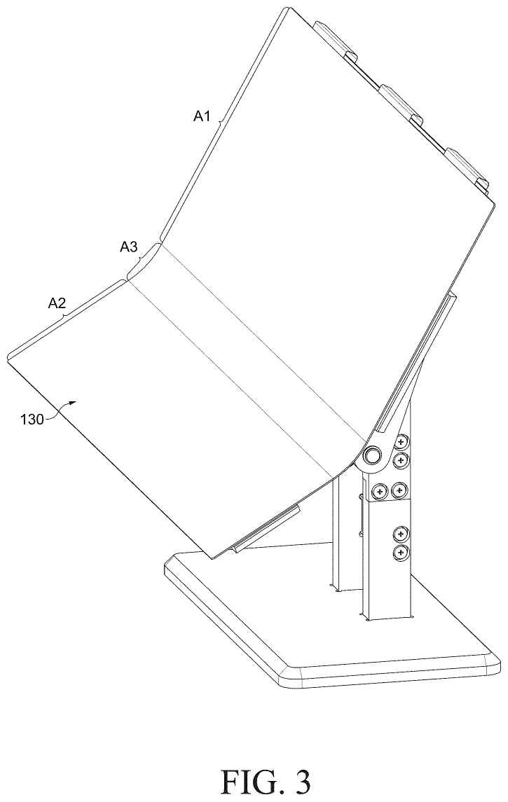

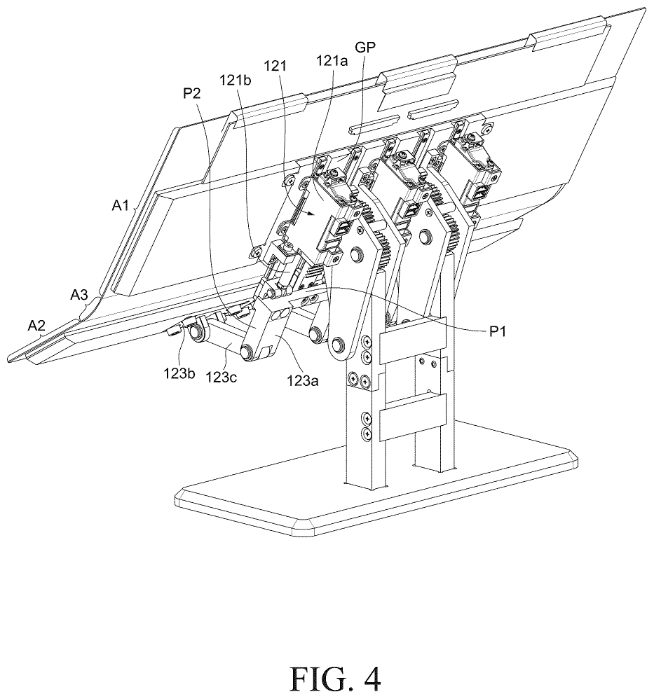

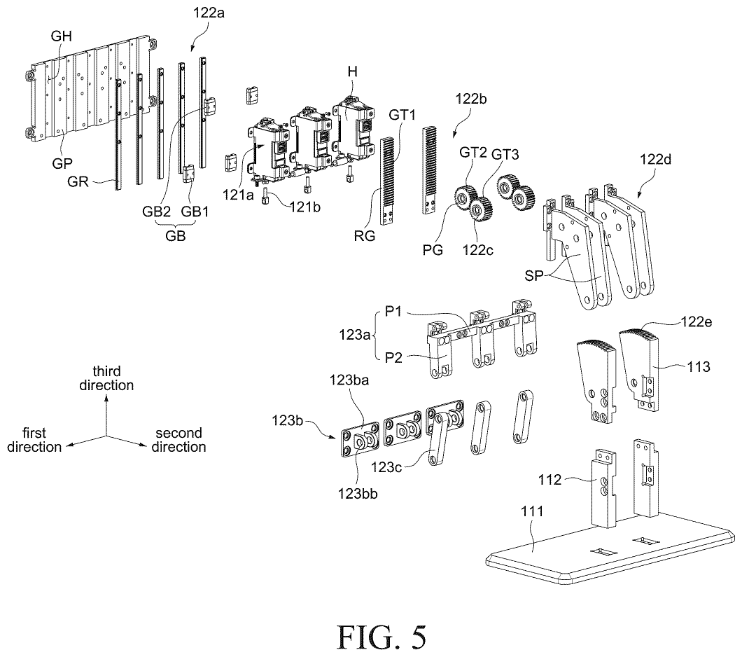

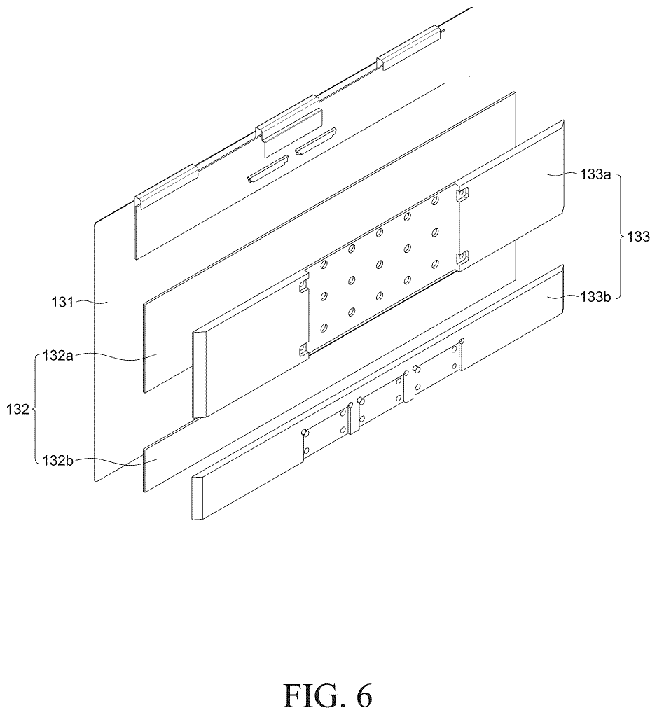

FIG. 1 is a front perspective view of a bendable display device according to an example embodiment of the present disclosure, FIG. 2 is a rear perspective view of a bendable display device according to an example embodiment of the present disclosure, and FIG. 3 is a front perspective view of a state in which a bendable display device according to an example embodiment of the present disclosure is bent and rotated (or tilted). FIG. 4 is a rear perspective view of a bent display device according to an example embodiment of the present disclosure as bent and rotated (or tilted), FIG. 5 is an exploded perspective view of a support and a driving module according to an example embodiment of the present disclosure, and FIG. 6 is an exploded perspective view of a display panel module according to an example embodiment of the present disclosure.

The bendable display device 100 according to an example embodiment of the present disclosure may be applied to a display panel module of a monitor or a display panel module inside a vehicle.

As illustrated in FIGS. 1 to 6, a bendable display device 100 according to an example embodiment of the present disclosure includes a support (or stand) 110, a driving module 120, and a display panel module 130.

The support 110 may support the driving module 120 and the display panel module 130. The driving module 120 may be rotatably coupled to the support 110.

The support 110 may include a support plate 111, a first support pillar 112, and a second support pillar 113.

The support plate 111 may support the first support pillar 112. As shown in FIG. 1, the support plate 111 may be formed in a plate shape extending along a first direction and a second direction, that is, a direction horizontally orthogonal to the first direction.

The first support pillar 112 may support the second support pillar 113. The first support pillar 112 may be coupled to an upper portion of the support plate 111.

The second support pillar 113 may be supported by the first support pillar 112. The second support pillar 113 may extend in the third direction, that is, in a vertical direction perpendicular to the first direction. The second support pillar 113 may be connected to an upper portion of the first support pillar 112. A tilting gear 122e may be formed on the upper surface of the second support pillar 113.

For structural stability, a plurality of first support pillars 112 and a plurality of second support pillars 113 may be provided. The bendable display device 100 according to an example embodiment of the present disclosure is described, and illustrated in the drawings, as having two first support pillars 112 and two second support pillar 113, but it is not limited thereto.

The driving module 120 may bend the display panel module 130 and rotate (or tilt) the display panel module 130. The driving module 120 may be rotatably connected to the support 110.

The driving module 120 may include one or more actuators 121, a first power transmission unit 122, and a second power transmission unit 123.

The actuator(s) 121 may generate power and transmit the generated power to the first power transmission unit 122 and the second power transmission unit 123.

An actuator 121 may include a driving motor 121a and a driving rod 121b.

The driving motor 121a may include a housing H and a driving source.

The housing H may serve as a body of the driving motor 121a. The housing H may be coupled to the guide plate GP.

The driving source may generate power. The driving source may be installed inside the housing H.

The driving source may be a portion of the driving motor 121a that substantially generates a driving force. A driving rod 121b may be moved by the driving force generated from the driving source.

The driving rod 121b may be movably coupled to the housing H.

The driving rod 121b may be connected to the first part P1 of the first link 123a. In the process of moving the driving rod 121b by receiving power from the driving source, the driving force generated by the driving source may be transmitted to the first link 123a.

A plurality of actuators 121 may be provided for driving stability. A plurality of actuators 121 may be spaced apart from each other in the first direction. Since the plurality of actuators 121 are spaced apart from each other along the first direction, the first part P1 of the first link 123a may be uniformly pressed. The actuators 121 may each be formed of a linear actuator but are not limited thereto.

The actuator(s) 121 may generate power, and power generated by the actuator(s) 121 may be transmitted to the first power transmission unit 122 and the second power transmission unit 123.

Specifically, the driving rod(s) 121b may press the first link 123a through the power generated by the driving motor(s) 121a. The driving rod(s) 121b may press the first link 123a and transmit power to the first power transmission unit 122. In addition, the driving rod(s) 121b may press the first link 123a and transmit power to the second power transmission unit 123.

The first power transmission unit 122 may receive power from the actuator(s) 121 and rotate (or tilt) the display panel module 130.

The first power transmission unit 122 may include a guide member 122a, at least one rack pinion (or rack and pinion) member 122b, at least one idle gear 122c, at least one pivot frame 122d, and at least one tilting gear 122e.

The guide member 122a may support the actuator(s) 121 and the rack and pinion member(s) 122b. The guide member 122a may be coupled to the display panel module 130. The actuator(s) 121 may be coupled to the guide member 122a.

The guide member 122a may include a guide plate GP, a plurality of guide rails GR, and a plurality of guide blocks GB.

The guide plate GP may be connected to the display panel module 130. The guide plate GP may be formed in a plate shape extending along the first direction and the third direction.

The guide plate GP may include one or more guide grooves GH.

A guide groove GH may be a portion where a guide rail GR is installed. The guide groove GH may be concavely formed on the rear surface of the guide plate GP (i.e., the surface facing the actuator(s) 121). The guide groove GH may extend in the third direction.

A plurality of guide grooves GH may be formed. The plurality of guide grooves GH may be spaced apart from each other along the first direction at the rear surface of the display panel module 130.

The guide plate GP may be coupled to the display panel module 130 and may support an upper portion of the display panel module 130, that is, a portion of the display panel module 130 that is not bent (the first display area A1).

A plurality of guide rails GR may be inserted into the plurality of guide grooves GH, respectively.

The plurality of guide rails GR may serve as movement paths of the plurality of guide blocks GB. The plurality of guide rails GR may extend along the third direction, and the length of the plurality of guide rails GR in the third direction may be longer than the length of the guide plate GP in the third direction.

The plurality of guide rails GR may be formed in a number corresponding to the plurality of guide grooves GH.

The plurality of guide rails GR may be inserted respectively into the plurality of guide grooves GH and be coupled to the guide plate GP. A lower portion of the guide rails GR may extend to a lower side of the guide plate GP and may extend beyond the lower end of the guide plate GP.

A plurality of guide blocks GB may be movably coupled to the plurality of guide rails GR, respectively. The plurality of guide rails GR may guide the movement of the plurality of guide blocks GB, respectively.

A plurality of first guide blocks GB1 may be movably coupled respectively to a lower portion of the guide rails GR extending below the lower end of the guide plate GP. Through the lower portion of the respective guide rails GR, the plurality of first guide blocks GB1 may move below the lower end of the guide plate GP and guide the movement of the links included in the second power transmission unit 123.

The plurality of guide blocks GB may guide the sliding movement of the respective rack gears RG and the first link 123a.

The plurality of guide blocks GB may include a plurality of first guide blocks GB1 and a plurality of second guide blocks GB2.

The plurality of first guide blocks GB1 and the plurality of second guide blocks GB2 may be alternately disposed on the plurality of guide rails GR. Specifically, the plurality of first guide blocks GB1 may be movably connected to the lower portion of the corresponding guide rails GR. The lower portion of the guide rails GR described above may be a portion of the guide rails GR that extends to the lower side of the display panel module 130 (below the lower end of the guide plate GP).

A first part P1 of the first link 123a may be coupled to the plurality of first guide blocks GB1. A plurality of first guide blocks GB1 may guide the sliding movement of the first link 123a.

A plurality of rack gears RG may be coupled to a plurality of second guide blocks GB2, respectively. A plurality of second guide blocks GB2 may guide the sliding movement of the rack gears RG, respectively. A rack pinion (or rack and pinion) member 122b may transmit the power of the corresponding actuator(s) 121 to the corresponding idle gear 122c.

Each rack and pinion member 122b may include a rack gear RG and a pinion gear PG.

The rack gear RG may transmit the power of the corresponding actuator(s) 121 to the corresponding pinion gear PG. Each rack gear RG may be a planar gear having a first gear teeth GT1. The first gear teeth GT1 may be formed along the third direction in the rack gear RG. The second gear teeth GT2 of the corresponding pinion gear PG may be engaged with the first gear teeth GT1.

The rack gear(s) RG may be coupled respectively to the second guide block(s) GB2. A first part P1 of the first link 123a may be coupled to a lower portion of the rack gear(s) RG. The pinion gear(s) PG may be engaged respectively with the rack gear(s) RG.

A rack gear RG may receive the power generated by the corresponding actuator(s) 121 through the first link 123a to slide vertically in the third direction and may rotate the corresponding pinion gear PG engaged in the sliding movement. That is, the rack gear RG may transmit the power generated by the corresponding actuator(s) 121 to the corresponding pinion gear PG.

A pinion gear PG may transmit power transmitted from the corresponding rack gear RG to the corresponding idle gear 122c. Each pinion gear PG may be a circular gear having a second gear teeth GT2. The second gear teeth GT2 may extend in the circumferential direction along the outer circumferential surface of the pinion gear PG. The first gear teeth GT1 of a rack gear RG may be engaged with the second gear teeth GT2 of the corresponding pinion gear PG. In addition, the third gear teeth GT3 of an idle gear 122c may be engaged with the second gear teeth GT2 of the corresponding pinion gear PG.

A pinion gear PG may be engaged with the corresponding rack gear RG and the corresponding idle gear 122c. The pinion gear PG may be disposed on the front side of the idle gear 122c inside a corresponding pivot frame 122d (i.e., between a corresponding pair of pivot plates SP). The pinion gear PG may be rotatably supported by the corresponding pair of pivot plates SP.

A pinion gear PG may rotate through the corresponding rack gear RG and rotate the engaged idle gear 122c. The pinion gear PG may transmit power received through the corresponding rack gear RG to the corresponding idle gear 122c.

An idle gear 122c may move along the corresponding tilting gear 122e and rotate the corresponding pivot frame 122d by the power provided from the corresponding pinion gear PG. The idle gear 122c may be a circular gear having a third gear teeth GT3. The third gear teeth GT3 may extend in the circumferential direction along the outer circumferential surface of the idle gear 122c. The second gear teeth GT2 of a pinion gear PG may be engaged with the third gear teeth GT3 of the corresponding idle gear 122c. In addition, a tilting gear 122e may be engaged with the third gear teeth GT3 of the corresponding idle gear 122c.

An idle gear 122c may be disposed at the rear side of the corresponding pinion gear PG. Both sides of the idle gear 122c may be rotatably supported by the corresponding pair of pivot plates SP.

An idle gear 122c rotates through the corresponding pinion gear PG and may move in a clockwise direction (or counterclockwise direction) along the corresponding tilting gear 122e. The idle gear 122c may tilt the corresponding pivot frame 122d through power transmitted through the corresponding pinion gear PG.

A pivot frame 122d may be rotated by the corresponding idle gear 122c and may tilt the display panel module 130. The pivot frame 122d may be fixed to the guide plate GP and may be rotatably connected to the support 110.

A pivot frame 122d may include a pair of pivot plates SP.

A pair of pivot plates SP may be disposed to face each other with a tilting gear 122e interposed therebetween. A lower portion of the pair of pivot plates SP may be rotatably connected to the corresponding second support pillar 113. The front side of the pair of pivot plates SP may be fixed to the display panel module 130.

A pair of pivot plates SP can be rotated while the corresponding idle gear 122c moves along the corresponding tilting gear 122e to tilt the display panel module 130.

A tilting gear 122e may guide movement of the corresponding idle gear 122c. The tilting gear 122e may be formed on the corresponding second support pillar 113 of the support 110. Each tilting gear 122e may be formed to be round or curved. The tilting gear 122e may be formed along a circumferential direction of a circle centering on a virtual axis parallel to the first direction. The tilting gear 122e may be formed within a preset angle range on the upper surface of the corresponding second support pillar 113.

The extension length of a tilting gear 122e (i.e., the length of the arc of the tilting gear 122e) may correspond to the length of the corresponding rack gear RG. Since the extension length of the tilting gear 122e corresponds to the length of the corresponding rack gear RG, when the corresponding idle gear 122c moves along the tilting gear 122e in conjunction with movement of the corresponding rack gear RG, the corresponding idle gear 122c may not be deviated to the outside of the tilting gear 122e.

An idle gear 122c may be engaged with the corresponding tilting gear 122e. Since the idle gear 122c moves clockwise (or counterclockwise) through the corresponding tilting gear 122e, the display panel module 130 may rotate or tilt.

The second power transmission unit 123 may bend the display panel module 130 by pressing the lower portion of the display panel module 130. The second power transmission unit 123 is connected to the lower portion of the display panel module 130 and may be supported by the first power transmission unit 122.

The second power transmission unit 123 may include a first link 123a, one or more second links 123b, and one or more third links 123c.

The first link 123a may transmit the power of the actuator(s) 121 to the second link(s) 123b and the third link(s) 123c and simultaneously transmit the power of the actuator(s) 121 to the rack gear(s) RG.

The first link 123a may include a first part P1 and one or more second parts P2.

The first part P1 may extend along the first direction. An upper portion of the first part P1 may be connected to the actuator 121(s), and a front side of the first part P1 may be coupled to the first guide block(s) GB1.

One or more second parts P2 may extend downward from the first part P1. A plurality of second parts P2 may be formed and may be spaced apart from each other in the first direction. A third link 123c may be rotatably connected to the corresponding second part P2 of the first link 123a.

The first link 123a may be moved by receiving power from the actuator(s) 121 through the first part P1 and may transmit power to the third link(s) 123c respectively through the second part(s) P2. The movement of the above-described first link 123a means movement in a direction parallel with respect to the guide plate GP.

Further, the first link 123a moves through the power of the actuator(s) 121 and may synchronize the driving of the first power transmission unit 122 and the second power transmission unit 123. A tilting operation of the display panel module 130 through the rack and pinion member(s) 122b, the idle gear(s) 122c, the pivot frame(s) 122d, and the tilting gear(s) 122e and a bending operation of the display panel module 130 through the second link(s) 123b and the third link(s) 123c may be simultaneously performed through the first link 123a.

The second link(s) 123b may press a lower portion of the display panel module 130.

Each second link 123b may include a rib 123ba coupled to the display panel module 130 and a hinge 123bb coupled to the corresponding third link 123c.

A rib 123ba may support the display panel module 130, and A third link 123c may be rotatably connected to the corresponding hinge 123bb. A second link 123b may receive the power from the corresponding third link 123c to press a lower portion (i.e., the second display area A2) of the display panel module 130 to bend the second display area A2 to be inclined with respect to the first display area A1.

A third link 123c may transmit the power transmitted from the first link 123a to the corresponding second link 123b. Each third link 123c may have a bar shape. The third link 123c may be disposed to be inclined downward from one end (the upper end as illustrated in the drawings) toward the other end (the lower end as illustrated in the drawings).

A third link 123c may be rotatably connected to the first link 123a and the corresponding second link 123b. One end (the upper end in the drawings) of the third link 123c may be rotatably connected to the corresponding second part P2 of the first link 123a, and the other end (the lower end in the drawings) of the third link 123c may be rotatably connected to the corresponding second link 123b. The second link 123b and the third link 123c may be formed in a binary link structure.

The third link(s) 123c may be rotated within a preset angle range. Since the third link(s) 123c are disposed to be inclined downward and rotate within a preset angle range, when the third link(s) 123c receive power from the actuator(s) 121, the second link(s) 123b may be pressed toward the display panel module 130. In the basic mode (i.e., the first position) of the display panel module 130, the third link(s) 123c may be disposed to be inclined with respect to the rear surface of the display panel module 130 without being parallel to the first link 123a. Therefore, when switching to the bending mode (i.e., the second position), the third link(s) 123c may rotate toward the display panel module 130 and press the second link(s) 123b, and the second link(s) 123b pressed by the third link(s) 123c may bend the display panel module 130 in the set direction.

Specifically, the third link(s) 123c may be pressed by the first link 123a to rotate with respect to the first link 123a. In this process, the second link(s) 123b may be pressed by the third link(s) 123c to rotate with respect to the third link(s) 123c. During a process of rotating the second link(s) 123b with respect to the third link(s) 123c, a part of the display panel module 130 may be bent by the second link 123b.

The display panel module 130 is a panel for displaying an image.

The display panel module 130 may be disposed at one of a first position disposed flat vertically (for example, disposed along the third direction) and a second position disposed to be inclined by bending a part thereof. The display panel module 130 may be rotated (or tilted) by the driving module 120 between the first position and the second position and may be disposed at a specific position between the first position and the second position.

The display panel module 130 may include a display panel 131, a back plate 132, and a fastening plate 133, as illustrated, for example, in FIG. 6.

The display panel 131 includes a display element for displaying an image, a driving element for driving the display element, and wiring lines for transmitting various signals to and between the display element and the driving element.

The display element may be differently defined depending on the type of the display panel 131. Where the display panel 131 is an organic light emitting panel, the display element may be an organic light emitting element including an anode, an organic emission layer, and a cathode. Where the display panel 131 is a liquid crystal panel module, the display element may be a liquid crystal display element.

Hereinafter, even though the display panel 131 may be described as an organic light emitting panel as an example, the display panel 131 is not limited to the organic light emitting panel.

The display panel 131 may be disposed at a first position (basic mode) disposed flat in the vertical direction (e.g., disposed parallel to the third direction) or at a second position (bending mode) in which the lower portion is bent by the driving module 120 and the upper portion (and the central portion) is rotated to be inclined or tilted.

The above-described bending means that the lower portion of the display panel 131 is disposed to be inclined or bent with respect to the upper portion of the display panel 131 and may also mean that a part of the display panel 131 connecting the lower portion of the display panel 131 with the upper portion of the display panel 131 may be formed to be rounded or curved. Further, the above-described rotation means that the display panel 131 is rotated clockwise or counterclockwise to dispose the upper portion of the display panel 131 to be inclined with respect to the support 110.

As illustrated in FIGS. 3 and 4, the display panel 131 may include a first display area A1, a second display area A2, and a third display area A3.

The second display area A2 on the display panel 131 may be an area located below the first display area A1.

When the second display area A2 is disposed to be inclined or bent with respect to the first display area A1 by the driving module 120, the inclination angle of the second display area A2 may be larger than the inclination angle of the first display area A1 by the bent third display area A3.

The third display area A3 may be an area between the first display area A1 and the second display area A2. The third display area A3 may be an area leading from the first display area A1 to the second display area A2.

The third display area A3 may be disposed along the vertical direction or may be bent by driving the driving module 120. The third display area A3 may be rounded to have a preset curvature by driving the driving module 120.

As shown, e.g., in FIG. 6, The back plate 132 may support the display panel 131.

The back plate 132 may include a first back plate 132a and a second back plate 132b.

The first back plate 132a may be coupled to a position corresponding to the first display area A1 of the display panel 131 and may support the first display area A1 of the display panel 131.

The second back plate 132b may be coupled to a position corresponding to the second display area A2 of the display panel 131 and may support the second display area A2 of the display panel 131.

The back plate 132 may be formed of a thin film formed of polyimide PI, polyethylene naphthalate PEN, polyethylene terephthalate PET, or a combination of these polymers, but is not limited thereto.

The fastening plate 133 may connect the back plate 132 with the guide plate GP and the second link(s) 123b.

The fastening plate 133 may include a first fastening plate 133a and a second fastening plate 133b.

The first fastening plate 133a may be coupled to the first back plate 132a. The first fastening plate 133a may reinforce the strength of the first back plate 132a and connect the guide plate GP and the display panel 131.

The second fastening plate 133b may be coupled to the second back plate 132b. The second fastening plate 133b may reinforce the strength of the second back plate 132b and connect the second link(s) 123b and the display panel 131.

The fastening plate 133 may include a metal material like steel use stainless (SUS) or Invar or a plastic material. However, the material of the fastening plate 133 may be variously changed depending on the design or specification as long as it satisfies physical property conditions like the amount of thermal deformation, radius of curvature, and/or rigidity, but is not limited thereto.

The controller (not shown) may control the operation of the driving module 120.

The controller may control the display panel module 130 to switch the arrangement state of the display panel module 130 between a basic mode, in which the display panel module 130 is disposed flat vertically (that is, a state in which the display panel module 130 is in the first position), and a bending mode in which the display panel module 130 is bent and disposed to be inclined (that is, a state in which the display panel module 130 is in the second position).

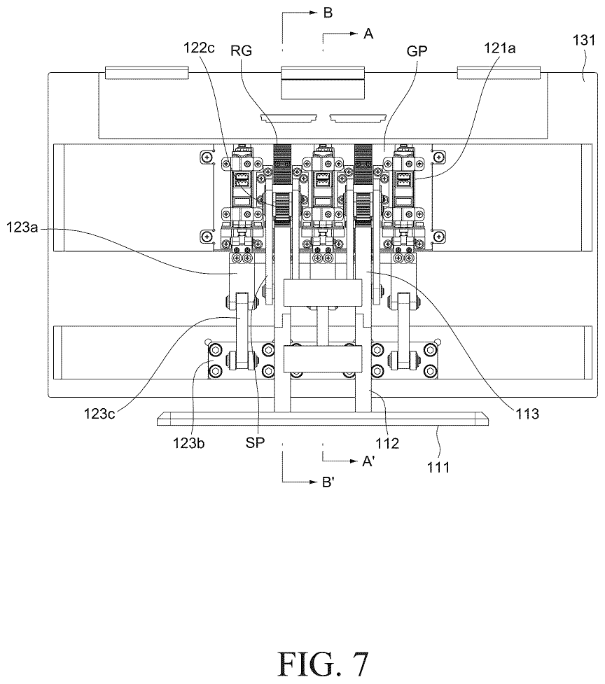

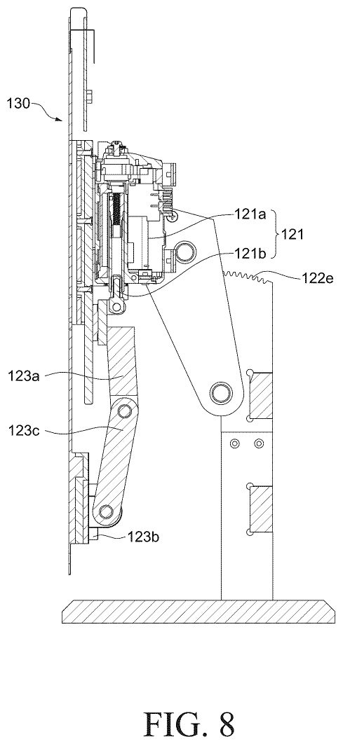

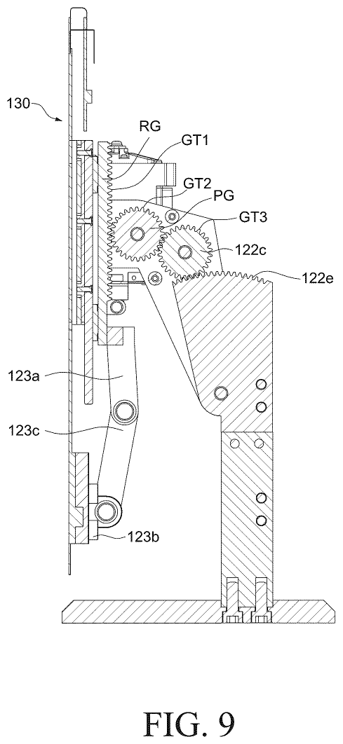

FIG. 7 is a rear view of a bendable display device in which a display panel module according to an example embodiment of the present disclosure is configured at a first position, FIG. 8 is a cross-sectional view along line A-A′ in FIG. 7, and FIG. 9 is a cross-sectional view along line B-B′ in FIG. 7.

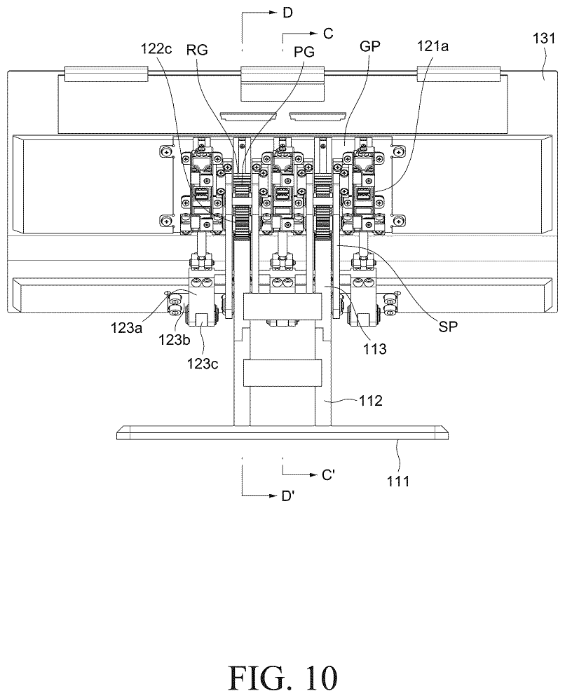

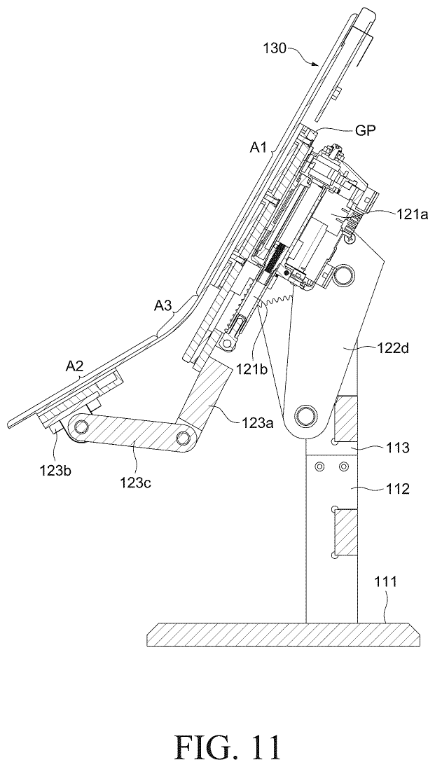

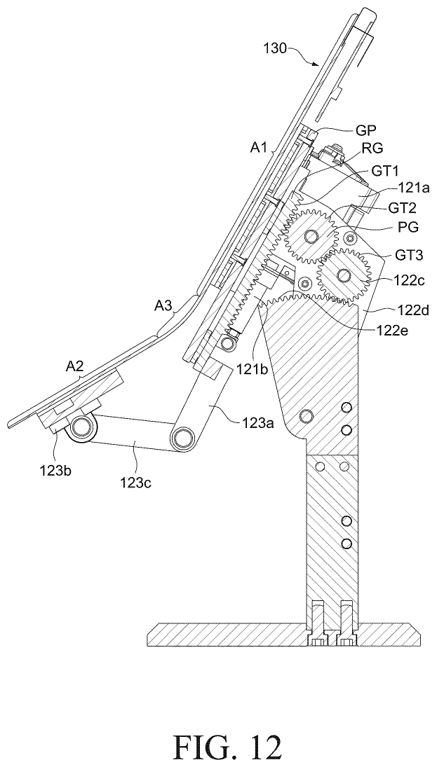

FIG. 10 is a rear view of a bendable display device in which a display panel module according to an example embodiment of the present disclosure is configured at a second position, FIG. 11 is a cross-sectional view along line C-C′ in FIG. 10, and FIG. 12 is a cross-sectional view along line D-D′ in FIG. 10.

Hereinafter, a process in which the bendable display device 100 according to an example embodiment of the present disclosure may be simultaneously rotated and bent will be described with reference to FIGS. 7 to 12.

A placement state of the display panel module 130 may be changed from a first position (i.e., a basic mode) illustrated, for example, in FIGS. 7 to 9, to a second position (i.e., a bending mode) illustrated, for example, in FIGS. 10 to 12.

Specifically, when the actuator(s) 121 are driven, the first link 123a moves, and the bending driving of the display panel module 130 and the rotational driving of the display panel module 130 may be simultaneously performed in conjunction with the movement of the first link 123a.

Hereinafter, the bending driving of the display panel module 130 and the rotational driving of the display panel module 130 will be separately described.

The bending driving of the display panel module 130 may be performed as follows.

When the driving motor(s) 121a generate power, the driving rod 121b may move to the lower side of the driving motor 121a through the generated power. The driving rod(s) 121b may move downward and press the first link 123a. The pressed first link 123a may move downward.

In conjunction with the downward movement of the first link 123a, the third link(s) 123c may be rotated clockwise. The first link 123a may move and press the third link 123c. The inclined third link 123c may be rotated (i.e., rotated clockwise when viewed from the direction as shown, e.g., in FIGS. 8, 9, 11, and 12) in an inclined direction by the downward pressure on the first link 123a.

In conjunction with clockwise rotation of the third link(s) 123c, the second link(s) 123b may move along the clockwise direction. Since the second link(s) 123b are connected respectively to the third link(s) 123c in a binary link structure, the second link(s) 123b may move (e.g., in a circular arc motion) along a curved trajectory within a predetermined radius.

The lower portion of the display panel module 130 may be pressed in conjunction with the movement of the second link(s) 123b. The lower portion of the display panel module 130 may be pressed by the second link(s) 123b, and the lower portion of the display panel module 130 may be bent. The lower portion (e.g., the second display area A2) may be disposed to be inclined or bent with respect to the upper portion (e.g., the first display area A1) of the display panel module 130, and the portion (e.g., the third display area A3) connecting the upper portion and the lower portion of the display panel module 130 may be rounded to have a curvature. Accordingly, the shape of the display panel module 130 may be in a bent state.

The rotational driving of the display panel module 130 may be interlocked with the above-described bending driving, and the rotational driving may be performed as follows.

In conjunction with the downward movement of the first link 123a pressed by the driving rod(s) 121b, the rack gear(s) RG may be moved along a direction parallel to the guide plate GP.

In conjunction with the movement of the rack gear(s) RG, the pinion gear(s) PG may be rotated counterclockwise (e.g., when viewed from the direction as shown, e.g., in FIGS. 9 and 12).

In conjunction with the counterclockwise rotation of the pinion gear(s) PG, the idle gear(s) 122c may be rotated clockwise.

The idle gear(s) 122c may rotate clockwise and move (e.g., in a circular arc motion) along a curved trajectory on the upper surface of the tilting gear(s) 122e. In conjunction with the curved trajectory movement of the idle gear(s) 122c, the pivot frame(s) 122d may be tilted.

As the pivot frame(s) 122d are tilted, the display panel module 130 may also be rotated (tilted). Accordingly, as the display panel module 130 is rotated, the arrangement state is changed (e.g., to an inclined or tilted state), and the display panel module 130 may be disposed in the second position.

As described above, when the display panel module 130 is disposed in the second position (i.e., the bending mode), in the state in which the lower portion of the display panel module 130 is bent, the arrangement state of the display panel module 130 is changed to the inclined state so that a maximized or enhanced curved surface may be provided to the user.

Hereinafter, a process of returning the display panel module 130 from the second position to the original position (i.e., the first position) will be described with reference to FIGS. 7 to 12.

In a state in which the display panel module 130 is disposed in the second position, the driving rod(s) 121b may move to the inside of the respective driving motor(s) 121a by the driving source and pull the first link 123a. The pulled first link 123a may move to be closer to the driving motor(s) 121a.

The pulled first link 123a may move to be closer to the driving motor(s) 121a, and the rack gear(s) RG may move in conjunction with the upward movement of the first link 123a.

In conjunction with sliding of the rack gear(s) RG, the pinion gear(s) PG may be rotated clockwise (e.g., when viewed from the direction as illustrated, e.g., in FIGS. 9 and 12) and in conjunction with the clockwise rotation of the pinion gear(s) PG, the idle gear(s) 122c may be rotated counterclockwise.

The idle gear(s) 122c may rotate in the counterclockwise direction and may move (e.g., in a circular arc motion) in the counterclockwise direction along a curved trajectory on the upper surface of the tilting gear(s) 122e. In conjunction with the curved trajectory movement of the idle gear(s) 122c, the pivot frame(s) 122d may be tilted counterclockwise, and as the pivot frame 122d is tilted, the display panel module 130 may also be tilted together with the pivot frame(s) 122d to return to the first position (basic mode).

In addition, in conjunction with the upward movement of the first link 123a, the third link(s) 123c may be rotated counterclockwise (e.g., when viewed from the direction as illustrated, e.g., in FIGS. 9 and 12). While the first link 123a moves upward, the third link(s) 123c may be pulled upward. The third link(s) 123c may be rotated counterclockwise by a pulling force of the first link 123a.

In conjunction with the counterclockwise rotation of the third link(s) 123c, the second link(s) 123b may move along the counterclockwise direction. The second link(s) 123b may move (e.g., in a circular arc motion) along a curved trajectory within a preset radius and return the display panel module 130 to a position before being bent (e.g., the first position).

The bendable display device 100 according to example embodiments of the present disclosure may bend and rotate the display panel module 130 through the driving module 120. Through the bending and rotating movement, a maximized or enhanced sense of curvature can be provided to the user, and the contents may be viewed from various angles desired by the user. Further, in the bendable display device 100 according to example embodiments of the present disclosure, it is possible to switch between a basic mode and a bending mode, and when not in use, it is possible to increase space efficiency by switching to the basic mode.

The bendable display device according to example embodiments of the present disclosure can be described as follows.

According to an aspect of the present disclosure, a bendable display device includes a support, a driving module rotatably coupled to the support, and having an actuator and a plurality of power transmission units connected to the actuator, and a display panel module coupled to the driving module and bendable, wherein one of the plurality of power transmission units is configured to receive power from the actuator to rotate the display panel module, and another of the plurality of power transmission units is configured to receive power from the actuator to bend at least a portion of the display panel module.

In one or more aspects of the present disclosure, the driving module may drive the display panel module to be rotated between a first position and a second position inclined with respect to the first position.

In one or more aspects of the present disclosure, the plurality of power transmission units may include a first power transmission unit and a second power transmission unit, the second power transmission unit may be movable by the actuator, and transmit power to the first power transmission unit.

In one or more aspects of the present disclosure, the actuator may include a housing coupled to the first power transmission unit, a driving motor having a driving source installed inside the housing, and a driving rod movably connected to the housing and connected to the second power transmission unit.

In one or more aspects of the present disclosure, the first power transmission unit may include a guide member coupled to the display panel module and having an actuator installed therein, a rack and pinion member connected to the second power transmission unit, an idle gear movably coupled to the rack and pinion member, a pivot frame rotatably connected to the support, fixed to the guide member, and rotatably supporting the rack and pinion member and the idle gear, and a tilting gear connected to the support and movably coupled to the idle gear.

In one or more aspects of the present disclosure, the second power transmission unit may include a first link connected to the actuator and to the rack and pinion member and movable by the actuator, a second link fixed to a lower portion of the display panel module, and a third link having one side rotatably connected to the first link and the other side rotatably connected to the second link and inclined toward the second link.

In one or more aspects of the present disclosure, the third link may be configured to be moved in conjunction with a movement of the first link to adjust an inclination angle, the third link being rotatable within a preset angle range, and the second link may be configured to adjust a bending angle of the display panel module according to an adjustment of the inclination angle of the third link.

In one or more aspects of the present disclosure, the guide member may include a guide plate coupled to the display panel module and having a plurality of guide grooves, a plurality of guide rails installed in the plurality of guide grooves, respectively, and a plurality of guide blocks movably coupled respectively to the plurality of guide rails, each of the guide blocks being connected to a corresponding one of the first link and the rack and pinion member.

In one or more aspects of the present disclosure, the rack and pinion member may include a rack gear coupled to a corresponding one of the plurality of guide blocks and connected to the first link, and a pinion gear coupled to the rack gear and the idle gear. The rack gear may receive power of the actuator through the first link.

In one or more aspects of the present disclosure, the display panel module may include a first display area, a second display area bendable with respect to the first display area, and a third display area connected between the first display area and the second display area, the third display area having a curvature when the second display area is bent with respect to the first display area.

In one or more aspects of the present disclosure, the first display area may be tiltable by the driving module to be inclined, and an inclination angle of the first display area in an inclined state may be smaller than an inclination angle of the second display area with respect to a vertical direction.

In one or more aspects of the present disclosure, the bendable display device may further include a controller configured to control an operation of the driving module to drive the display panel module to switch between a first position of being vertically flat and a second position of being inclined from a vertical direction and bent.

According to another aspect of the present disclosure, a display device includes: a display panel configured to display an image, the display panel having a first area and a second area bendable with respect to the first area; a stand supporting the display panel; an actuator at a rear surface of the display panel; a first power transmission unit connected between the actuator and the stand, and configured to be driven by the actuator to tilt the display panel; and a second power transmission unit connected between the actuator and the display panel, and configured to be driven by the actuator to bend the second area of the display panel with respect to the first area.

In one or more aspects of the present disclosure, the first power transmission unit and the second power transmission unit may be configured to be driven by the actuator simultaneously to tilt the display panel and bend the second area of the display panel, respectively.

In one or more aspects of the present disclosure, the first power transmission unit may be configured to be driven by the actuator to tilt the entire display panel, and the second power transmission unit may be configured to be driven by the actuator to bend only the second area of the display panel with respect to the first area of the display panel.

In one or more aspects of the present disclosure, the actuator may include a housing coupled to the first power transmission unit, a driving motor having a driving source installed inside the housing, and a driving rod movably connected to the housing and connected directly to the second power transmission unit.

In one or more aspects of the present disclosure, the first power transmission unit may include: a guide member connected between the rear surface of the display panel and the actuator; a rack and pinion member connected to the second power transmission unit; an idle gear movably coupled to the rack and pinion member; a pivot frame rotatably connected to the stand, fixed to the guide member, and rotatably supporting the rack and pinion member and the idle gear; and a tilting gear connected to the stand and movably coupled to the idle gear.

In one or more aspects of the present disclosure, the second power transmission unit may include: a first link connected to the driving rod of the actuator and to the rack and pinion member, the first link being movable by the actuator; a second link fixed to a lower portion of the display panel; and a third link having one side rotatably coupled to the first link and the other side rotatably coupled to the second link, the third link being inclined toward the display panel.

In one or more aspects of the present disclosure, the third link may be configured to be rotatably moved based on a movement of the first link to adjust an inclination angle, the third link being rotatable within a preset angle range, and the second link may be configured to adjust a bending angle of the display panel according to an adjustment of the inclination angle of the third link.

In one or more aspects of the present disclosure, the guide member may include: a guide plate coupled to the rear surface of the display panel and having a plurality of guide grooves; a plurality of guide rails installed in the plurality of guide grooves, respectively; and a plurality of guide blocks movably coupled respectively to the plurality of guide rails, each of the guide blocks being connected to a corresponding one of the first link and the rack and pinion member. The rack and pinion member may include a rack gear coupled to a corresponding one of the plurality of guide blocks and connected to the first link, and a pinion gear coupled to the rack gear and the idle gear. The rack gear may be configured to be moved by the actuator through the first link.

Although example embodiments of the present disclosure have been described in detail with reference to the accompanying drawings, the present disclosure is not limited thereto and may be embodied in various other forms without departing from the technical concept of the present disclosure. Therefore, these example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure may be construed based on the following claims and their equivalents, and all the technical concepts in the equivalent scope thereof should be construed as falling within the scope of the present disclosure.

What is claimed is:

1. A bendable display device, comprising:
a support;
a driving module rotatably coupled to the support, and having an actuator and a plurality of power transmission units connected to the actuator; and
a display panel module coupled to the driving module and bendable,
wherein one of the plurality of power transmission units is configured to receive power from the actuator to rotate the display panel module, and
wherein another of the plurality of power transmission units is configured to receive power from the actuator to bend at least a portion of the display panel module.

2. The bendable display device of claim 1, wherein the driving module drives the display panel module to be rotated between a first position and a second position inclined with respect to the first position.

3. The bendable display device of claim 1, wherein:
the plurality of power transmission units includes a first power transmission unit and a second power transmission unit;
the second power transmission unit is configured to receive power from the actuator; and
transmit power to the first power transmission unit.

4. The bendable display device of claim 3, wherein the actuator includes:
a housing coupled to the first power transmission unit;
a driving motor having a driving source installed inside the housing; and
a driving rod movably connected to the housing and connected to the second power transmission unit.

5. The bendable display device of claim 3, wherein the first power transmission unit includes:
a guide member coupled to the display panel module and in which the actuator is installed;
a rack and pinion member connected to the second power transmission unit;
an idle gear movably coupled to the rack and pinion member;
a pivot frame rotatably connected to the support, fixed to the guide member, and rotatably supporting the rack and pinion member and the idle gear; and
a tilting gear connected to the support and movably coupled to the idle gear.

6. The bendable display device of claim 5, wherein the second power transmission unit includes:
a first link connected to the actuator and to the rack and pinion member, the first link being movable by the actuator;
a second link fixed to a lower portion of the display panel module; and
a third link having one side rotatably connected to the first link and the other side rotatably connected to the second link, the third link being inclined toward the second link.

7. The bendable display device of claim 6, wherein:
the third link is configured to be moved in conjunction with a movement of the first link to adjust an inclination angle, the third link being rotatable within a preset angle range, and
the second link is configured to adjust a bending angle of the display panel module according to an adjustment of the inclination angle of the third link.

8. The bendable display device of claim 6, wherein the guide member includes:
a guide plate coupled to the display panel module and having a plurality of guide grooves;
a plurality of guide rails installed in the plurality of guide grooves, respectively; and
a plurality of guide blocks movably coupled respectively to the plurality of guide rails, each of the guide blocks being connected to a corresponding one of the first link and the rack and pinion member.

9. The bendable display device of claim 8, wherein the rack and pinion member includes:
a rack gear coupled to a corresponding one of the plurality of guide blocks and connected to the first link; and
a pinion gear coupled to the rack gear and the idle gear, and
wherein the rack gear receives power of the actuator through the first link.

10. The bendable display device according to claim 9, wherein the extension length of the tilting gear corresponds to the length of the rack gear.

11. The bendable display device of claim 1, wherein the display panel module includes:
a first display area;
a second display area bendable with respect to the first display area; and
a third display area connected between the first display area and the second display area, the third display area having a curvature when the second display area is bent with respect to the first display area.

12. The bendable display device of claim 11, wherein:
the first display area is tiltable by the driving module to be inclined; and
an inclination angle of the first display area in an inclined state is smaller than an inclination angle of the second display area with respect to a vertical direction.

13. The bendable display device of claim 11, further comprising:
a controller configured to control an operation of the driving module to drive the display panel module to switch between a first position of being vertically flat and a second position of being inclined from a vertical direction and bent.

14. A display device, comprising:
a display panel configured to display an image, the display panel having a first area and a second area bendable with respect to the first area;
a stand supporting the display panel;
an actuator at a rear surface of the display panel;
a first power transmission unit connected between the actuator and the stand, and configured to be driven by the actuator to tilt the display panel; and
a second power transmission unit connected between the actuator and the display panel, and configured to be driven by the actuator to bend the second area of the display panel with respect to the first area.

15. The display device of claim 14, wherein the first power transmission unit and the second power transmission unit are configured to be driven by the actuator simultaneously to tilt the display panel and bend the second area of the display panel, respectively.

16. The display device of claim 14, wherein:
the first power transmission unit is configured to be driven by the actuator to tilt the entire display panel; and
the second power transmission unit is configured to be driven by the actuator to bend only the second area of the display panel with respect to the first area of the display panel.

17. The display device of claim 14, wherein the actuator includes:
a housing coupled to the first power transmission unit;
a driving motor having a driving source installed inside the housing; and
a driving rod movably connected to the housing and connected directly to the second power transmission unit.

18. The display device of claim 17, wherein the first power transmission unit includes:
a guide member connected between the rear surface of the display panel and the actuator;
a rack and pinion member connected to the second power transmission unit;
an idle gear movably coupled to the rack and pinion member;
a pivot frame rotatably connected to the stand, fixed to the guide member, and rotatably supporting the rack and pinion member and the idle gear; and
a tilting gear connected to the stand and movably coupled to the idle gear.

19. The display device of claim 18, wherein the second power transmission unit includes:
a first link connected to the driving rod of the actuator and to the rack and pinion member, the first link being movable by the actuator;
a second link fixed to a lower portion of the display panel; and
a third link having one side rotatably coupled to the first link and the other side rotatably coupled to the second link, the third link being inclined toward the display panel.

20. The display device of claim 19, wherein:
the third link is configured to be rotatably moved based on a movement of the first link to adjust an inclination angle, the third link being rotatable within a preset angle range; and
the second link is configured to adjust a bending angle of the display panel according to an adjustment of the inclination angle of the third link.

21. The display device of claim 19, wherein:
the guide member includes:
a guide plate coupled to the rear surface of the display panel and having a plurality of guide grooves;
a plurality of guide rails installed in the plurality of guide grooves, respectively; and
a plurality of guide blocks movably coupled respectively to the plurality of guide rails, each of the guide blocks being connected to a corresponding one of the first link and the rack and pinion member;
the rack and pinion member includes:
a rack gear coupled to a corresponding one of the plurality of guide blocks and connected to the first link; and
a pinion gear coupled to the rack gear and the idle gear; and
the rack gear is configured to be moved by the actuator through the first link.
